(19) United States
(12) Patent Application Publication
(10) Pub. No.: US 2013/0192669 A1
(43) Pub. Date: Aug. 1, 2013

(54) PHOTOELECTRIC DEVICE

(71) Applicants: Hyun-Chul KIM, Yongin-si (KR); Sang-Hyun Eom, Yongin-si (KR)

(72) Inventors: Hyun-Chul KIM, Yongin-si (KR); Sang-Hyun Eom, Yongin-si (KR)

(21) Appl. No.: 13/552,017

(22) Filed: Jul. 18, 2012

Related U.S. Application Data
(60) Provisional application No. 61/592,721, filed on Jan. 31, 2012.

(51) Int. Cl. H01L 31/0224

(52) U.S. Cl. 136/256

(57) ABSTRACT

A photoelectric device, includes a first substrate, the first substrate having first grid electrodes and a light absorption layer disposed between neighboring first grid electrodes, and a second substrate, the second substrate facing the first substrate and having at least one second grid electrode that faces the light absorption layer.

### CROSS-REFERENCE TO RELATED APPLICATION

The present application claims priority under 35 U.S.C. §119(e) to U.S. Provisional Application No. 61/592,721, filed on Jan. 31, 2012, and entitled: “Photoelectric Device,” which is incorporated herein by reference in its entirety.

### BACKGROUND

1. Field

One or more embodiments relate to a photoelectric device.

2. Description of the Related Art

Extensive research has recently been conducted on photoelectric devices that convert light into electric energy. From among such devices, solar cells utilizing sunlight have attracted attention as alternative energy sources to fossil fuels.

Research on solar cells having various working principles has been continuously conducted. From among such solar cells, dye-sensitized solar cells have remarkably high photoelectric conversion efficiency compared with typical solar cells and thus are attracting attention as next generation solar cells.

### SUMMARY

Embodiments are directed to a photoelectric device, including a first substrate, the first substrate having first grid electrodes and a light absorption layer disposed between neighboring first grid electrodes, and a second substrate, the second substrate facing the first substrate and having at least one second grid electrode that faces the light absorption layer.

The first grid electrodes and the at least one second grid electrode may be offset so as not to face each other.

Multiple second grid electrodes may be disposed between the neighboring first grid electrodes, and the second grid electrodes may have a smaller pitch than the first grid electrodes.

Each of the second grid electrodes disposed between the neighboring first grid electrodes may face the light absorption layer.

A first group of second grid electrodes may be disposed below the light absorption layer, and an adjacent second group of second grid electrodes may be disposed below another light absorption layer, and a first pitch of second grid electrodes in the first group of second grid electrodes may be smaller than a second pitch of the adjacent first and second groups of second grid electrodes.

The photoelectric device may further include a catalyst layer that covers the at least one second grid electrode, the catalyst layer having a surface having a concave shape.

The concave shape of the catalyst layer may be such that a deposition height of the catalyst layer, relative to the second substrate, is reduced away from the at least one second grid electrode.

At least two second grid electrodes may be disposed between the neighboring first grid electrodes, the at least two second grid electrodes may be covered by protective layers, and the catalyst layer may have a first deposition height, relative to the second substrate, between electrodes of the at least two second grid electrodes, and may have a second deposition height, relative to the second substrate, at edges of the protective layers, the first deposition height being less than the second deposition height.

A first plurality of second grid electrodes may be disposed below the light absorption layer, and an adjacent second plurality of second grid electrodes may be disposed below another light absorption layer, and a catalyst layer may cover the first and second pluralities of second grid electrodes, a deposition height, relative to the second substrate, of a portion of the catalyst layer between the electrodes of the first plurality of second grid electrodes being higher than a deposition height, relative to the second substrate, of a portion of the catalyst layer between the first and second pluralities of second grid electrodes.

A first conductive layer may be interposed between the first substrate and the first grid electrodes, and a second conductive layer may be interposed between the second substrate and the at least one second grid electrode.

The photoelectric device may further include a catalyst layer covering the at least one second grid electrode, the catalyst layer contacting the second conductive layer.

Embodiments are also directed to a photoelectric device, including a first substrate, the first substrate having a light absorption layer and first grid electrodes for extracting light-generated carriers of the light absorption layer, the first grid electrodes having a first pitch, and a second substrate, the second substrate facing the first substrate and having second grid electrodes, the second grid electrodes having a second pitch, the second pitch being less than the first pitch.

The photoelectric device may further include a catalyst layer disposed between the second grid electrodes, the catalyst layer having a surface having a concave shape.

The concave shape of the catalyst layer may be such that a deposition height of the catalyst layer, relative to the second substrate, is reduced away from the second grid electrodes.

A light absorption layer may be disposed between neighboring first grid electrodes, and multiple second grid electrodes may be disposed below the light absorption layer.

The photoelectric device may further include a catalyst layer disposed between the second grid electrodes. A first group of second grid electrodes may be disposed below the light absorption layer, and an adjacent second group of second grid electrodes may be disposed below another light absorption layer, and a deposition height, relative to the second substrate, of a portion of the catalyst layer between the second grid electrodes of the first group may be higher than a deposition height, relative to the second substrate, of a portion of the catalyst layer between the first and second groups.

Embodiments are also directed to a photoelectric device, including a first substrate, a second substrate, the second substrate facing the first substrate and being spaced apart from the first substrate, a dye-sensitized semiconductor layer on the first substrate, two first finger electrodes on the first substrate, the dye-sensitized semiconductor layer being between the first finger electrodes, and a finger electrode group on the second substrate, the finger electrode group including at least one finger electrode, the finger electrode group facing the dye-sensitized semiconductor layer and being spaced apart laterally from the first finger electrodes.

The dye-sensitized semiconductor layer may be substantially centered between the two first finger electrodes, and the finger electrode group may be substantially centered under the dye-sensitized semiconductor layer.

The photoelectric device may further include a catalyst layer on the second substrate. The finger electrode group may include at least two finger electrodes with a gap therebetween, and the catalyst layer may substantially fill the gap, the catalyst layer having a concave surface in the gap.

### BRIEF DESCRIPTION OF THE DRAWINGS

Features will become apparent to those of skill in the art by describing in detail exemplary embodiments with reference to the attached drawings in which:

FIG. 1 illustrates an exploded perspective view of a photoelectric device according to an example embodiment;

FIG. 2 illustrates a cross-sectional view of the photoelectric device taken along

II-II of FIG. 1;

FIG. 3 illustrates a cross-sectional view of a photoelectric device according to a comparative example;

FIGS. 4 through 6 illustrate cross-sectional views of photoelectric devices according to Examples 1 through 3; and

FIGS. 7A through 7C illustrate simulation results in which resistance distribution of a second conductive layer varies as the number of second grid electrodes varies.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

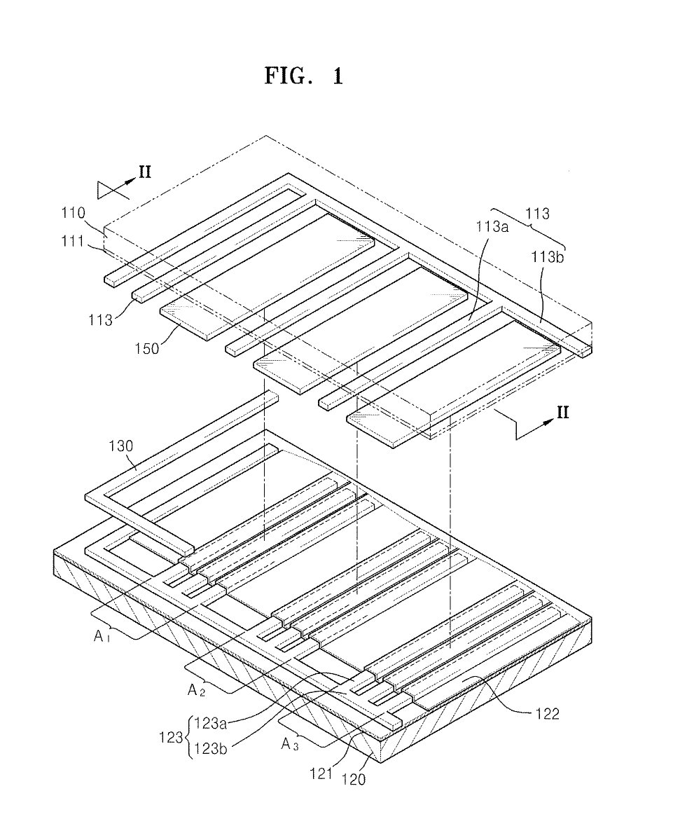

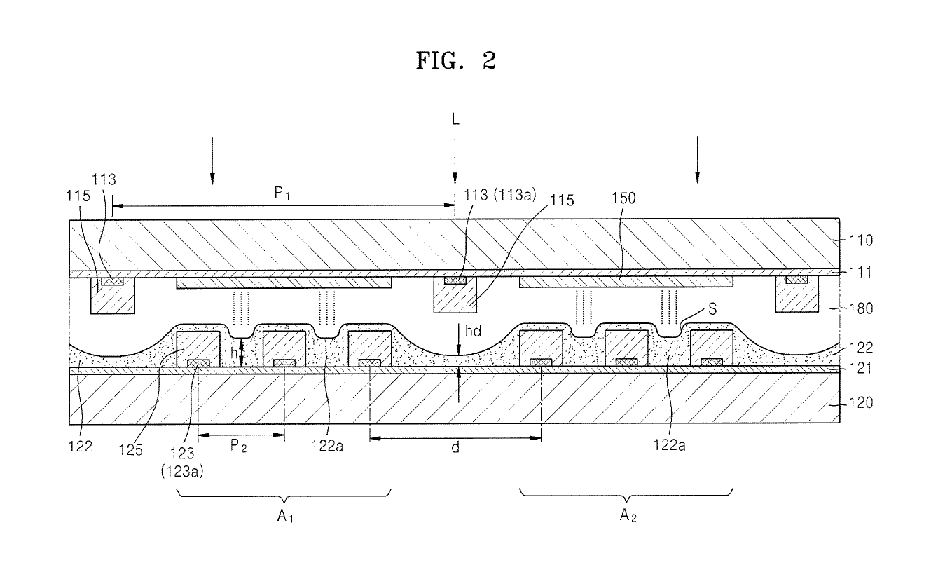

FIG. 1 illustrates an exploded perspective view of a photoelectric device according to an example embodiment. FIG. 2 is a cross-sectional view of the photoelectric device taken along II-II of FIG. 1.

Referring to FIGS. 1 and 2, a first substrate 110, on which first grid electrodes 113 are disposed, and a second substrate 120, on which second grid electrodes 123 are disposed, may be disposed to face each other. A sealing member 130 (only a portion thereof being shown in FIG. 1) may be interposed between the first substrate 110 and the second substrate 120. Light absorption layers 150 and a catalyst layer 122 may be disposed adjacent the first and second grid electrodes 113 and 123, respectively.

For example, the light absorption layers 150 may be patterned between neighboring first grid electrodes 113 on the first substrate 110. In an implementation, the light absorbing layers 150 may not overlap the first grid electrodes 113. The catalyst layer 122 may be disposed on the second substrate 120 so as to overlap and cover the second grid electrodes 123. Examples of positions where the light absorption layers 150 and the catalyst layer 122 are disposed are shown in FIGS. 1 and 2.

The first substrate 110 may serve as a light receiving surface, and the first grid electrodes 113 disposed on the first substrate 110 may serve as negative electrodes from which light-generated carriers (electrons) are extracted. The second substrate 120 may be disposed opposite to the light receiving surface, and the second grid electrodes 123 disposed on the second substrate 120 may serve as positive electrodes for accepting a current passing through an external circuit (not shown). Thus, the first and second grid electrodes 113 and 123 may respectively serve as negative and positive electrodes that are two electrodes of a photoelectric circuit.

First and second conductive layers 111 and 121 may be respectively disposed on the first and second substrates 110 and 120. The first and second conductive layers 111 and 121, together with the first and second substrates 110 and 120, may constitute conductive substrates. The first and second grid electrodes 113 and 123 may be respectively disposed on the first and second conductive layers 111 and 121, and may reinforce conductivity of the first and second conductive layers 111 and 121 so as to reduce electric resistance.

The first grid electrodes 113 may include a plurality of first finger electrodes 113a, each of which may extend in parallel to each other in a stripe pattern, and a first collector electrode 113b that intersects the first finger electrodes 113a and is electrically connected to the first finger electrodes 113a.

The second grid electrodes 123 may include a plurality of second finger electrodes 123a, each of which may extend in parallel to each other in a stripe pattern, and a second collector electrode 123b that intersects the second finger electrodes 123a and is electrically connected to the second finger electrodes 123a.

The first and second collector electrodes 113b and 123b may serve as electrical contact points with an external circuit (not shown) or may be electrically connected to another photoelectric device (not shown) so as to constitute a module structure.

Hereinafter, when the terms ‘the first and second grid electrodes 113 and 123’ are used without distinguishing the first and second finger electrodes 113a and 123a from the first and second collector electrodes 113b and 123b, the first and second grid electrodes 113 and 123 may refer to the first and second finger electrodes 113a and 123a, respectively. For example, when the first and second grid electrodes 113 and 123 are disposed or the first and second grid electrodes 113 and 123 are respectively arranged at first and second electrode pitches, the first and second grid electrodes 113 and 123 may refer to the first and second finger electrodes 113a and 123a, respectively.

The first and second grid electrodes 113 and 123 may be asymmetrically disposed. In an implementation, the first and second grid electrodes 113 and 123 may be disposed to be out of line or offset, so as not to face each other.

In an implementation, the first finger electrodes 113a may not overlap the second finger electrodes 123a. In an implementation, each of the light absorption layers 150 may be disposed between neighboring first grid electrodes 113. The second grid electrodes 123 may be disposed to respectively face the light absorption layers 150 and, thus, may be respectively disposed below the light absorption layers 150. For example, the second grid electrodes 123 may be densely arranged below the light absorption layers 150 and may include different groups A1, A2, and A3 that are respectively arranged below corresponding light absorption layers 150.

The light absorption layers 150 and the second grid electrodes 123 may be stacked on each other so as to overlap each other, thereby reinforcing an electrical field between the light absorption layers 150 and the second grid electrodes 123 to facilitate transfer of electrons to the light absorption layers 150, which will now be described in more detail.

The photoelectric device may be implemented as a dye-sensitized solar cell (DSSC). A dye-sensitized solar cell may include a photosensitive dye that receives visible light and generates excited electrons, a semiconductor material that receives the excited electrons, and an electrolyte that reacts with electrons returning from an external circuit. Thus, the light absorption layers 150 may absorb incident light L and may generate carriers (electrons). The light absorption layers 150 that are oxidized by extracting the light-generated carriers may be reduced again through the catalyst layer 122 that provides electrons, using an electrolyte 180 as a medium. In this case, since the catalyst layer 122 accepts through the second conductive layer 121 a flow of electrons passing through the second grid electrodes 123, catalyst layer portions 122a of the catalyst layer 122, which are adjacent to the second grid electrodes 123 and contact directly the second conductive layer 121, for example, the catalyst layer portions 122a between neighboring second grid electrodes 123 or the catalyst layer portions 122a adjacent to the second grid electrodes 123, may contribute significantly to reduction of the light absorption layers 150. Thus, the second grid electrodes 123 and the light absorption layers 150 may be disposed to face each other such that the catalyst layer portions 122a adjacent to the second grid electrodes 123 may closely and approximately face the light absorption layers 150, thereby reinforcing an electrical field to facilitate transfer of electrons to the light absorption layers 150.

In addition, the light absorption layers 150 and the second grid electrodes 123 may be stacked on each other so as to overlap each other, and a gap between the light absorption layers 150 and the second grid electrodes 123 may be reduced, thereby increasing carrier mobility. For example, the light absorption layers 150 and the catalyst layer portions 122a adjacent to the second grid electrodes 123 may closely and approximately face each other, thereby reducing a path for transferring electrons.

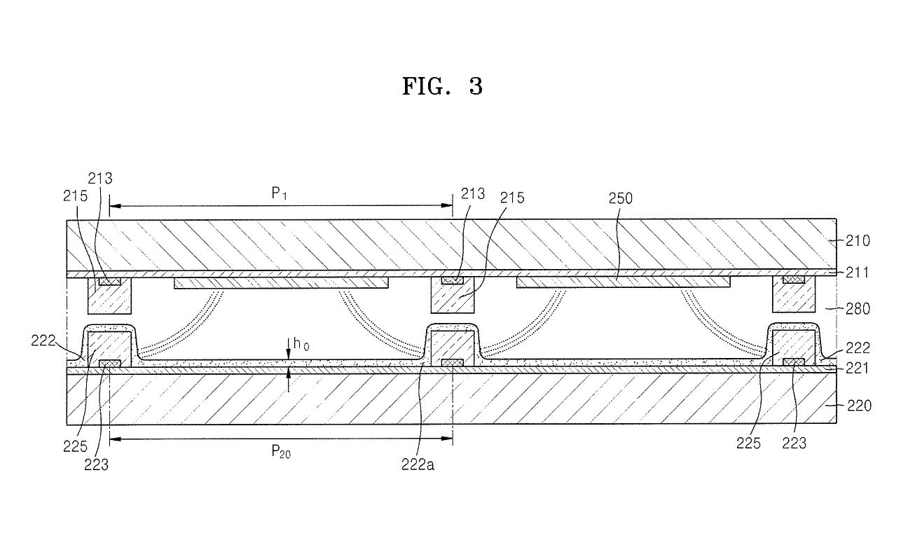

FIG. 3 illustrates a cross-sectional view of a photoelectric device according to a comparative example. It will be understood that the comparative examples is set forth to highlight certain characteristics of certain embodiments, and is not to be construed as either limiting the scope of the invention or as necessarily being outside the scope of the invention in every respect.

Referring to FIG. 3, a first substrate 210, on which first grid electrodes 213 are disposed, and a second substrate 220, on which second grid electrodes 223 are disposed, may be disposed to face each other. First and second conductive layers 211 and 221 are disposed on the first and second substrates 210 and 220, respectively.

The first and second grid electrodes 213 and 223 may be disposed to face each other, such that the first and second grid electrodes 213 and 223 overlap as shown in FIG. 3. A light absorption layer 250 is disposed between neighboring first grid electrodes 213. According to the comparative example, a gap between the light absorption layers 250 and the second grid electrodes 223 is increased and an electrical field formed through an electrolyte 280 is weakened, thereby reducing carrier mobility. Thus, since a gap between the light absorption layers 250 and catalyst layer portions 222a adjacent to the second grid electrodes 223 is increased, resistance of a current path is increased, thereby reducing a fill factor and reducing photoelectric conversion efficiency.

As shown in FIG. 3, as an electrode pitch P20 of the second grid electrodes 223 is increased, a deposition height h0 (relative to the second substrate) of a portion of a catalyst layer 222 between the second grid electrodes 223 is reduced. Where the deposition height h0 of the catalyst layer 222 is reduced, a low density catalyst layer may be formed there, which may reduce electrolyte reduction efficiency of the catalyst layer 222. In FIG. 3, reference numerals 215 and 225 indicate protective layers covering the first and second grid electrodes 213 and 223, respectively.

Referring again to FIG. 2, the first grid electrodes 113 may be disposed at a first electrode pitch P1. The second grid electrodes 123 may be disposed at a second electrode pitch P2. The first and second electrode pitches P1 and P2 may be different from each other.

Not all of the first grid electrodes 113 or the second grid electrodes 123 may be spaced apart at the same pitch. For example, the first and second electrode pitches P1 and P2 of the first and second grid electrodes 113 and 123 may respectively refer to closest pitches of the first and second grid electrodes 113 and 123. In an implementation, when the second grid electrodes 123 are densely disposed below the light absorption layers 150, a pitch of the second grid electrodes 123 may correspond to the second electrode pitch P2.

The first grid electrodes 113 may be spaced apart from each other at the first electrode pitch P1. The light absorption layers 150 may each be interposed between neighboring first grid electrodes 113 and may be arranged in the first electrode pitch P1, which is relatively wide, so as to receive as much incident light L as possible.

With regard to the arrangement of the second grid electrodes 123, the second grid electrodes 123 of a first group A1 are disposed below one of the light absorption layers 150, and the second grid electrodes 123 of a second group A2 are disposed below another one of the light absorption layers 150. In this case, the second grid electrodes 123 of the first group A1 may be densely arranged at the second electrode pitch P2. Similarly, the second grid electrodes 123 of the second group A2 may be densely arranged at the second electrode pitch P2. In addition, the second grid electrodes 123 of the first group A1 and the second grid electrodes 123 of the second group A2 may be spaced apart from each other at a pitch ‘d’ that is greater than the second electrode pitch P2. Thus, the inter-group pitch, i.e., the pitch ‘d’ of neighboring second grid electrodes 123 from among the second grid electrodes 123 of the first group A1 and the second group A2, may be greater than the intra-group pitch, i.e., the second electrode pitch P2.

The first and second grid electrodes 113 and 123 may be formed on different sides, i.e., on the first and second substrates 110 and 120, respectively. The first grid electrodes 113 of the light receiving surface may have a higher aperture ratio than the second grid electrodes 123 of the opposite side so as to receive as much incident light L as possible.

The aperture ratio refers to a relative ratio of portions of a substrate that are exposed between the first and second grid electrodes 113 and 123, i.e., the substrate except for portions that are occupied by the first and second grid electrodes 113 and 123, relative to the entire substrate. The first and second grid electrodes 113 and 123 may be formed of an opaque metal material and thus the aperture ratio may refer to a ratio of an effective incident area for receiving incident light.

The first grid electrodes 113 of the light receiving surface may be designed to have a higher aperture ratio than the second grid electrodes 123 of the opposite side. A large amount of the incident light L may be received by the first grid electrodes 113, thereby increasing efficiency of the photoelectric device. In an implementation, the first electrode pitch P1 may be greater than the second electrode pitch P2 (P1>P2).

The second grid electrodes 123 may be disposed opposite to the light-receiving side. Thus, the aperture ratio of the second side may be less than that of the light-receiving side. Thus, the second electrode pitch P2 may be small and the second grid electrodes 123 may be densely arranged, thereby providing a current path with low resistance and help reduce or eliminate efficiency losses due to resistance.

The second grid electrodes 123 may receive a flow of current passing through an external circuit (not shown) and may respectively distribute reduction electrons to sections of the photoelectric device. The catalyst layer 122 may be disposed between the second grid electrodes 123. Thus, the catalyst layer portions 122a adjacent the second grid electrodes 123 may be accommodated between neighboring second grid electrodes 123 and may be accommodated in a recess between the second electrodes, which corresponds to the second electrode pitch P2.

The catalyst layer 122 may be formed across the second substrate 120. The catalyst layer portions 122a adjacent to the second grid electrodes 123, i.e., the catalyst layer portions 122a between the second grid electrodes 123, may significantly contribute to photoelectric transformation. Thus, a deposition height h of the catalyst layer 122 between the second grid electrodes 123 may be important. The deposition height h of the catalyst layer 122 may correspond to a density of the catalyst layer 122. As the deposition height h is increased, a catalyst layer 122 with higher density may be advantageously formed in a same area.

The second grid electrodes 123 may increase the deposition height h of the catalyst layer 122. As shown in FIGS. 1 and 2, a free surface S of the catalyst layer 122 may have a curve shape, which may increase a surface area thereof and facilitate electron transfer with the electrolyte. The catalyst layer 122 may be closely attached to two walls of each of the second grid electrodes 123, i.e., two walls of each of protective layers 125, and may have recesses having a concave shape. Thus, the catalyst layer 122 may have a highest deposition height at a portion where the catalyst layer 122 is closely attached to the walls of each of the second grid electrodes 123, and may have recesses having a concave shape such that the deposition height h is reduced away from the second grid electrodes 123.

The protective layers 125 of the second grid electrodes 123 may provide attachment surfaces to which the catalyst layer 122 is attached. Thus, the deposition height h of the catalyst layer 122 may be increased and the catalyst layer 122 with high density may be formed in a same area. When the second electrode pitch P2 is small, electrical conductivity may be increased and a resistance loss may be reduced, while the catalyst layer 122 with high density may be formed.

When the second grid electrodes 123 of the first group A1 (below the light absorption layer 150) and the second grid electrodes 123 of the second group A2 (below another, adjacent light absorption layer 150) are arranged, a deposition height h of the catalyst layer 122 between the second grid electrodes 123 of the first group A1 may be greater than a deposition height hd of the catalyst layer 122 between the second grid electrodes 123 of the first group A1 and the second group A2. The second grid electrodes 123 that are densely arranged below the light absorption layers 150, i.e., the protective layers 125 of the second grid electrodes 123, may provide the attachment surfaces to which the catalyst layer 122 is attached.

Hereinafter, components of the photoelectric device will be described in more detail with reference to FIGS. 1 and 2.

The first and second substrates 110 and 120 may be formed of a transparent material and may be formed of a material having high light transmittance. For example, the first and second substrates 110 and 120 may be a glass substrate or a resin film. The resin film may be flexible and may be suitable for use that requires flexibility.

The first and second conductive layers 111 and 121 that are respectively disposed on the first and second substrates 110 and 120 may be formed of a transparent conductive material having electrical conductivity and optical transparency, such as a transparent conductive oxide (TCO), for example, indium tin oxide (ITO), fluorine-dope tin oxide (FTO), antimony tin oxide (ATO), or the like.

The first and second grid electrodes 113 and 123 that are respectively disposed on the first and second substrates 110 and 120 may be formed of an opaque metal material having high electrical conductivity, for example, aluminum (Al), silver (Ag), or the like. The first and second grid electrodes 113 and 123 may be covered by protective layers 115 and 125, respectively. The protective layers 115 and 125 may prevent electrodes from corroding due to reaction with the electrolyte 180.

The light absorption layers 150 formed between the first grid electrodes 113 may include a semiconductor layer and a photosensitive dye adsorbed onto the semiconductor layer. The semiconductor layer may be formed of a metal oxide that includes, e.g., cadmium (Cd), zinc (Zn), indium (In), lead (Pb), molybdenum (Mo), tungsten (W), antimony (Sb), titanium (Ti), silver (Ag), manganese (Mn), tin (Sn), zirconium (Zr), strontium (Sr), gallium (Ga), silicon (Si), chromium (Cr), or the like.

The photosensitive dye adsorbed onto the semiconductor layer may include molecules that absorb light in a visible band and cause electrons to rapidly move from a light excitation state to the semiconductor layer. For example, the photosensitive dye may include a ruthenium-based photosensitive dye.

The catalyst layer 122 that fills between the second grid electrodes 123 and covers the second grid electrodes 123 may be formed of a material that serves as a reduction catalyst for providing electrons to the electrolyte 180 and may include, for example, a metal such as platinum (Pt), gold (Au), silver (Ag), copper (Cu), or aluminum (Al), a metal oxide such as zinc oxide, or a carbon-based material such as graphite. The electrolyte 180 between the light absorption layers 150 and the catalyst layer 122 may be a redox electrolyte including a pair of oxidant and reductant.

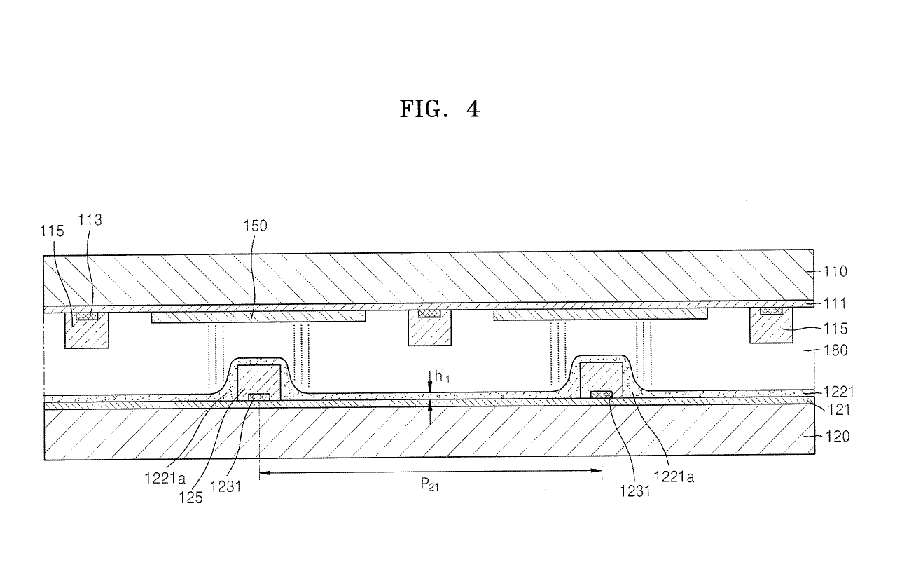

Table 1 below shows an open voltage Voc and a circuit current Isc, a fill factor (FF) calculated based thereon, and photoelectric conversion efficiency (Eff) with respect to different Examples 1 through 3. In addition, FIGS. 4 through 6 show structures according to Examples 1 through 3.

TABLE 1

| | Voc (V) | Isc (A) | FF | Eff (%) |
|---|---|---|---|---|
| Example 1 | 0.67 | 1.37 | 0.61 | 5.6 |
| Example 2 | 0.67 | 1.35 | 0.63 | 5.7 |
| Example 3 | 0.66 | 1.38 | 0.69 | 6.2 |

Referring to FIGS. 4 through 6, Examples 1 through 3 have a common technological feature in that the first grid electrodes 113 and second grid electrodes 1231, 1232, and 1233 are asymmetrically disposed, and may be disposed out of line so as not to face each other. In more detail, the light absorption layers 150 are disposed between neighboring first grid electrodes 113, and the second grid electrodes 1231, 1232, and 1233 are disposed to face the light absorption layers 150.

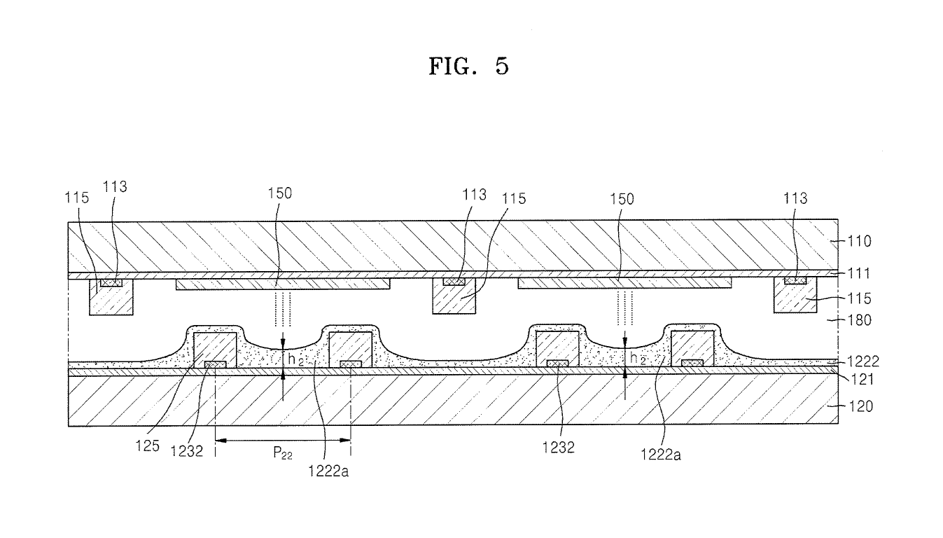

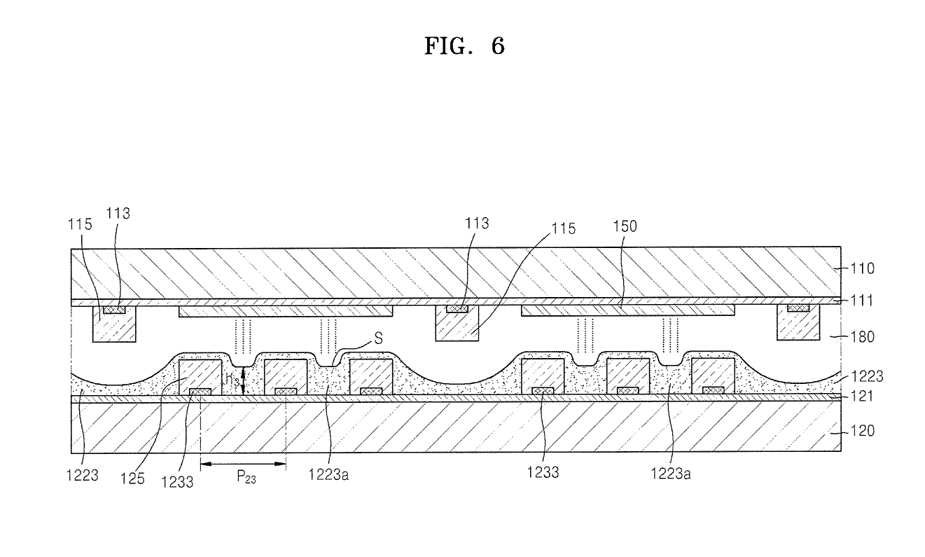

Examples 1 through 3 are different from each other in that the second grid electrodes 1231, 1232, and 1233 each have different numbers of electrodes disposed to correspond to the light absorption layers 150. Thus, in Example 1 of FIG. 4, a single grid electrode 1231 is disposed to correspond to each of the light absorption layers 150. In Example 2 of FIG. 5, two second grid electrodes 1232 are disposed to correspond to each of the light absorption layers 150. In Example 3 of FIG. 6, three second grid electrodes 1233 are disposed to correspond to each of the light absorption layers 150.

With regard to a photoelectric device that is designed such that the light absorption layers 150 have the same shape and the same size, e.g., 20 cm×5 cm, second electrode pitches P21, P22, and P23 may be different from each other by differentiating the numbers of the second grid electrodes 1231, 1232, and 1233 that are disposed for respective light absorption layers 150.

Based on the measurement results of a fill factor (FF) and photoelectric conversion efficiency (Eff) of Table 1, it is confirmed that output characteristics in Example 2 are excellent compared with Example 1, and that output characteristics in Example 3 are excellent compared with Example 2. In more detail, based on the measurement of a fill factor (FF), it is confirmed that a fill factor (FF) in Example 2 is increased by about 3.3% compared with Example 1, and that a fill factor (FF) in Example 3 is increased by about 9.5% compared with Example 2.

Based on the above, the second grid electrodes 1231, 1232, and 1233 may be densely arranged to improve the output characteristics of a photoelectric device. The output characteristics of the photoelectric device may vary according to the second electrode pitches P21, P22, and P23. For example, a resistance loss of the second grid electrodes 1231, 1232, and 1233 that constitute an optical current path may be reduced as the second grid electrodes 1231, 1232, and 1233 are more densely arranged. Thus, as the number of each of the second grid electrodes 1231, 1232, and 1233 disposed on the second conductive layer 121 having the same area is increased, direct current (DC) resistance of the optical current path may be reduced. Also, as the second grid electrodes 1231, 1232, and 1233 are more densely arranged to face the light absorption layers 150, an electrical field between the light absorption layers 150 and catalyst layers 1221, 1222, and 1223 may be further reinforced.

For example, the catalyst layers 1221, 1222, and 1223 receive through the second conductive layer 121 a flow of electrons passing through the second grid electrodes 1231, 1232, and 1233, and supply the received electrons to the light absorption layers 150. Thus, the catalyst layers 1221, 1222, and 1223 may be disposed across the second substrate 120. However, catalyst layer portions 1221a, 1222a, and 1223a, which are adjacent to the second grid electrodes 1231, 1232, and 1233 and contact directly the second conductive layer 121 (for example, the catalyst layer portions 1221a, 1222a, and 1223a adjacent to the second grid electrodes 1231, 1232, and 1233, or the catalyst layer portions 1221a, 1222a, and 1223a between the second grid electrodes 1231, 1232, and 1233) may significantly contribute to photoelectric transformation. In this case, the catalyst layer portions 1221a, 1222a, and 1223a adjacent to the second grid electrodes 1231, 1232, and 1233 may be disposed in a plurality of sections or may be disposed across a wide region by increasing the number of each of the second grid electrodes 1231, 1232, and 1233.

Referring to FIGS. 4 through 6, it may be confirmed that, as the number of each of the second electrode pitches P21, P22, and P23 is reduced, each of deposition heights h1, h2, and h3 of the catalyst layers 1221, 1222, and 1223 varies. The deposition heights h1, h2, and h3 of the catalyst layers 1221, 1222, and 1223 may correspond to densities with which the catalyst layers 1221, 1222, and 1223 are disposed. As the number of catalyst layers 1221, 1222, and 1223 is increased, the catalyst layers 1221, 1222, and 1223 may be formed with a higher density. For example, the catalyst layers 1221, 1222, and 1223 may be formed with a high density on the same area, thereby improving efficiency with respect to the same area.

The deposition heights h1, h2, and h3 of the catalyst layer portions 1221a, 1222a, and 1223a adjacent to the second grid electrodes 1231, 1232, and 1233 may have a significant effect. For example, comparing the deposition heights h1, h2, and h3 of the catalyst layers 1221, 1222, and 1223 between the second grid electrodes 1231, 1232, and 1233, the deposition height h2 in Example 2 is greater than the deposition height h1 in Example 1. In addition, the deposition height h3 in Example 3 is greater than the deposition height h2 in Example 2.

The deposition heights h1, h2, and h3 of the catalyst layers 1221, 1222, and 1223 adjacent to the second grid electrodes 1231, 1232, and 1233 may vary according to the second electrode pitches P21, P22, and P23, respectively, since the second grid electrodes 1231, 1232, and 1233 (i.e., the protective layers 125 of the second grid electrodes 1231, 1232, and 1233) provide attachment surfaces to which the catalyst layers 1221, 1222, and 1223 are attached, respectively. For example, in Example 2 of FIG. 5, the catalyst layer portion 1222a adjacent to the second grid electrodes 1232, i.e., the catalyst layer portion 1222a between the second grid electrodes 1232, is closely attached to two walls of each of the second grid electrode 1232 such that the deposition height h2 may be relatively high. In Example 3 of FIG. 6, it may be confirmed that, as the second electrode pitch P23 is reduced, a free surface of the catalyst layer 1223, which is recessed, is further planarized such that the deposition height h3 is increased.

As a result, as the second grid electrodes 1231, 1232, and 1233 are more densely arranged, a resistance loss of an optical current path may be further reduced. In addition, more of the second grid electrodes 1231, 1232, and 1233 may be arranged to face the light absorption layers 150 so as to reinforce an electrical field between the light absorption layers 150 and the catalyst layers 1221, 1222, and 1223, and the deposition heights h1, h2, and h3 of the catalyst layers 1221, 1222, and 1223 may be increased. Accordingly, a fill factor and photoelectric conversion efficiency may be increased, as shown in Table 1.

When the second electrode pitch P23 is further reduced compared to Example 3 of FIG. 6, a fill factor and photoelectric conversion efficiency may be increased. However, if the second electrode pitch P23 is too narrow, i.e., when the second grid electrodes 1233 are too densely arranged, an area occupied by portions of the catalyst layer 1223, which correspond to the second electrode pitch P23, may be reduced and an area occupied by the protective layers 125 covering the second grid electrodes 1233 may be increased. Thus, when many second grid electrodes 1233 are densely arranged within a limited area, an area occupied by the catalyst layer 1223 may be adversely affected. In addition, the number of the second grid electrodes 1233 may be determined based on manufacturing limitations. In an implementation, two or three second grid electrodes 1233 may be arranged to correspond to the light absorption layers 150.

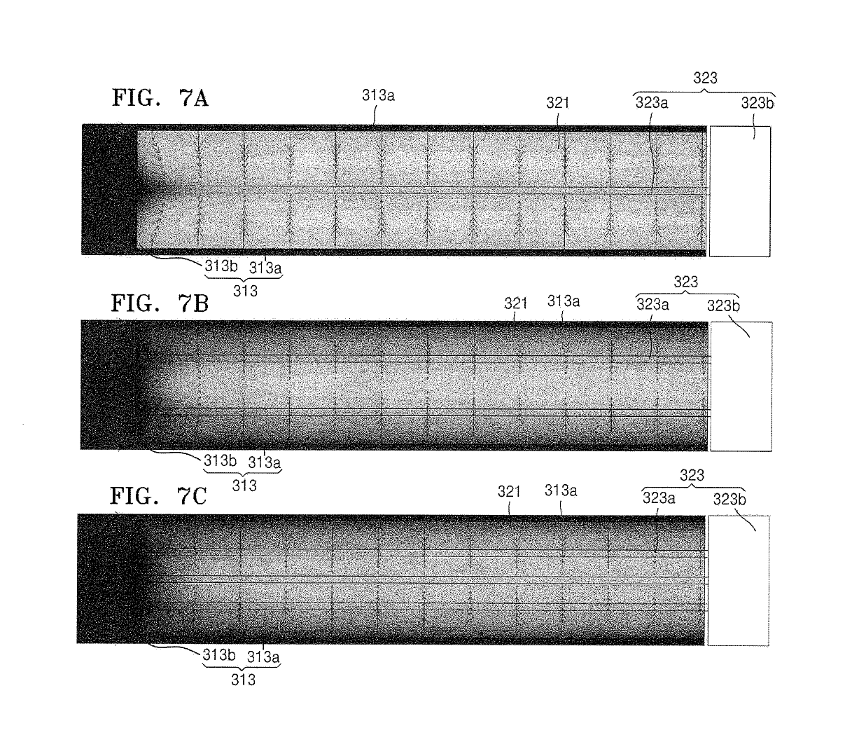

FIGS. 7A through 7C shows simulation results in which resistance distribution of a second conductive layer 321 varies as the number of second grid electrodes 323 varies. The current simulation is modeled such that first grid electrodes 313 include first finger electrodes 313a and a first collector electrode 313b, and the second grid electrodes 323 include second finger electrodes 323a and a second collector electrode 323b.

FIGS. 7A through 7C reflect common features in that the second finger electrodes 323a are arranged between the first finger electrodes 313a. However, FIG. 7A shows a case of one second finger electrode 323a. FIG. 7B shows a case of two second finger electrodes 323a. FIG. 7C shows a case of three second finger electrodes 323a. FIGS. 7A through 7C show electrical resistance distributions of the three cases.

As the number of the second finger electrodes 323a is increased, the overall brightness of the second conductive layer 321 gets darker, which means that electrical resistance on the second conductive layer 321 is reduced. With regard to a substrate having the same area, as the number of the second grid electrodes 323, i.e., the second finger electrodes 323a, having electrical conductivity is increased, electrical resistance is reduced.

The simulation results of FIGS. 7A through 7C support the experimental results of Table 1. The simulation results shows that electrical resistance of an optical current path is reduced, which is one ground upon which, as the number of the second grid electrodes 323, in particular, the second finger electrodes 323a is increased, the output characteristics of a photoelectric device may be improved.

By way of summation and review, one or more embodiments may include a photoelectric device having increased photoelectric conversion efficiency. According to the one or more of the above embodiments, first grid electrodes disposed on a light receiving surface and second grid electrodes disposed on an opposite surface may be differently designed such that light absorption layers and the second grid electrodes face each other. Thus, a photoelectric device may be provided with improved photoelectric conversion efficiency. In addition, the first grid electrodes and the second grid electrodes may be differently designed, such that an aperture ratio with respect to incident light is increased, which may reduce a resistance loss of a light current path and increase a deposition height of a catalyst layer while reducing an optical loss.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope as set forth in the following claims.

What is claimed is:

1. A photoelectric device, comprising:
a first substrate, the first substrate having first grid electrodes and a light absorption layer disposed between neighboring first grid electrodes; and
a second substrate, the second substrate facing the first substrate and having at least one second grid electrode that faces the light absorption layer.

2. The photoelectric device as claimed in claim 1, wherein the first grid electrodes and the at least one second grid electrode are offset so as not to face each other.

3. The photoelectric device as claimed in claim 1, wherein:
multiple second grid electrodes are disposed between the neighboring first grid electrodes, and
the second grid electrodes have a smaller pitch than the first grid electrodes.

4. The photoelectric device as claimed in claim 3, wherein each of the second grid electrodes disposed between the neighboring first grid electrodes faces the light absorption layer.

5. The photoelectric device as claimed in claim 3, wherein:
a first group of second grid electrodes is disposed below the light absorption layer, and an adjacent second group of second grid electrodes is disposed below another light absorption layer, and
a first pitch of second grid electrodes in the first group of second grid electrodes is smaller than a second pitch of the adjacent first and second groups of second grid electrodes.

6. The photoelectric device as claimed in claim 1, further comprising a catalyst layer that covers the at least one second grid electrode, the catalyst layer having a surface having a concave shape.

7. The photoelectric device as claimed in claim 6, wherein the concave shape of the catalyst layer is such that a deposition height of the catalyst layer, relative to the second substrate, is reduced away from the at least one second grid electrode.

8. The photoelectric device as claimed in claim 7, wherein:
at least two second grid electrodes are disposed between the neighboring first grid electrodes,
the at least two second grid electrodes are covered by protective layers, and
the catalyst layer has a first deposition height, relative to the second substrate, between electrodes of the at least two second grid electrodes, and has a second deposition height, relative to the second substrate, at edges of the protective layers, the first deposition height being less than the second deposition height.

9. The photoelectric device as claimed in claim 1, wherein:
a first plurality of second grid electrodes is disposed below the light absorption layer, and an adjacent second plurality of second grid electrodes is disposed below another light absorption layer, and
a catalyst layer covers the first and second pluralities of second grid electrodes, a deposition height, relative to the second substrate, of a portion of the catalyst layer between the electrodes of the first plurality of second grid electrodes being higher than a deposition height, relative to the second substrate, of a portion of the catalyst layer between the first and second pluralities of second grid electrodes.

10. The photoelectric device as claimed in claim 1, wherein:
a first conductive layer is interposed between the first substrate and the first grid electrodes, and
a second conductive layer is interposed between the second substrate and the at least one second grid electrode.

11. The photoelectric device as claimed in claim 10, further comprising a catalyst layer covering the at least one second grid electrode, the catalyst layer contacting the second conductive layer.

12. A photoelectric device, comprising:
a first substrate, the first substrate having a light absorption layer and first grid electrodes for extracting light-generated carriers of the light absorption layer, the first grid electrodes having a first pitch; and
a second substrate, the second substrate facing the first substrate and having second grid electrodes, the second grid electrodes having a second pitch, the second pitch being less than the first pitch.

13. The photoelectric device as claimed in claim 12, further comprising a catalyst layer disposed between the second grid electrodes, the catalyst layer having a surface having a concave shape.

14. The photoelectric device as claimed in claim 13, wherein the concave shape of the catalyst layer is such that a deposition height of the catalyst layer, relative to the second substrate, is reduced away from the second grid electrodes.

15. The photoelectric device as claimed in claim 12, wherein:
a light absorption layer is disposed between neighboring first grid electrodes, and
multiple second grid electrodes are disposed below the light absorption layer.

16. The photoelectric device as claimed in claim 15, further comprising a catalyst layer disposed between the second grid electrodes, wherein:
a first group of second grid electrodes is disposed below the light absorption layer, and an adjacent second group of second grid electrodes is disposed below another light absorption layer, and
a deposition height, relative to the second substrate, of a portion of the catalyst layer between the second grid electrodes of the first group is higher than a deposition height, relative to the second substrate, of a portion of the catalyst layer between the first and second groups.

17. A photoelectric device, comprising:
a first substrate;
a second substrate, the second substrate facing the first substrate and being spaced apart from the first substrate;
a dye-sensitized semiconductor layer on the first substrate;
two first finger electrodes on the first substrate, the dye-sensitized semiconductor layer being between the first finger electrodes; and
a finger electrode group on the second substrate, the finger electrode group including at least one finger electrode, the finger electrode group facing the dye-sensitized semiconductor layer and being spaced apart laterally from the first finger electrodes.

18. The photoelectric device as claimed in claim 17, wherein:
the dye-sensitized semiconductor layer is substantially centered between the two first finger electrodes, and
the finger electrode group is substantially centered under the dye-sensitized semiconductor layer.

19. The photoelectric device as claimed in claim 17, further comprising a catalyst layer on the second substrate, wherein:
the finger electrode group includes at least two finger electrodes with a gap therebetween, and
the catalyst layer substantially fills the gap, the catalyst layer having a concave surface in the gap.
